(19) United States
(12) Patent Application Publication
(10) Pub. No.: US 2006/0194449 A1
(43) Pub. Date: Aug. 31, 2006

(54) Resist pattern forming method and method of manufacturing semiconductor device

(76) Inventors: Tomoyuki Takeishi, Yokohama-shi (JP); Shinichi Ito, Yokohama-shi (JP); Yasunobu Onishi, Yokohama-shi (JP); Tsuyoshi Shibata, Kikuchi-gun (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/350,127

(22) Filed: Feb. 9, 2006

(30) Foreign Application Priority Data
Feb. 9, 2005 (JP) 2005-033393

(51) Int. Cl. H01L 21/31

(52) U.S. Cl. 438/781

(57) ABSTRACT

A resist pattern forming method includes forming a chemically amplified resist film on a substrate, forming a latent image in the resist film by irradiating an energy ray, contacting a liquid to a surface of the resist film, increasing temperature of the resist film to first temperature after the forming the latent image and the contacting, the first temperature being lower than a reaction start temperature at which an acid catalysis reaction occurs in the resist film, maintaining the temperature of the resist film at the first temperature for a predetermined time, increasing the temperature of the resist film to second temperature being not lower than the reaction start temperature after a lapse of the predetermined time, decreasing the temperature of the resist film increased to the second temperature to a temperature lower than the reaction start temperature, and developing the resist film after the decreasing the temperature.

### CROSS-REFERENCE TO RELATED APPLICATIONS

This application is based upon and claims the benefit of priority from prior Japanese Patent Application No. 2005-033393, Feb. 9, 2005, the entire contents of which are incorporated herein by reference.

### BACKGROUND OF THE INVENTION

1. Field of the Invention

The present invention relates to a resist pattern forming method and a method of manufacturing a semiconductor device wherein a resist pattern is formed by forming a latent image by performing an exposure via liquid on a resist film.

2. Description of the Related Art

An immersion exposure apparatus is a technique to perform an exposure to a chemically amplified resist film formed on a substrate to be processed, wherein the exposure is performed by filling a portion between a surface of the chemically amplified resist film and a lens of the exposure apparatus with liquid As a apparatus to be employed in such the exposure method, there is, for example, one disclosed in Jpn. Pat. Appln. KOKAI Publication No. 10-303114. In the document, there is disclosed a apparatus wherein the entire substrate to be processed is submerged in a stage which can supply liquid, and the exposure is performed by moving the stage relatively to the exposure apparatus. In such the configuration of the apparatus, the liquid is supplied to the entire stage, therefore, the liquid overflows from the stage when the stage is moved at a high speed or the like, and thus problem that the apparatus cannot be driven at a high speed is occurred.

With regard to countermeasures against liquid turbulence owing to the stage movement, there is disclosed a method for driving a stage while supplying a liquid partially to a portion to be exposed (Soichi Owa and Hiroyuki Nagasaka, Immersion lithography; its potential performance and issues, Proc. of SPIE Vol. 5040, pp. 724-733). The method enables the high speed movement of a stage.

However, when such a method of supplying the liquid partially is employed, there is a case where water is often left in an exposure area at the portion that the lens has left. As in the case, there is a treat that the remained water on a resist film or in the resist owing to the immersion exposure may be unevenly distributed on the entire substrate. If an acid catalysis reaction process (PEB) by heating is performed after the exposure of the chemically amplified resist film in this state, the water may stain, or temperature may decrease, therefore, problems such as resist pattern defect or the like occur.

### BRIEF SUMMARY OF THE INVENTION

According to an aspect of the present invention, there is provided a resist pattern forming method comprising: forming a chemically amplified resist film on a substrate; forming a latent image in the chemically amplified resist film by irradiating an energy ray onto a predetermined position on the chemically amplified resist film; contacting a liquid to a surface of the chemically amplified resist film; increasing temperature of the chemically amplified resist film to a first temperature after the forming the latent image and after the contacting, the first temperature being lower than a reaction start temperature at which an acid catalysis reaction occurs in the chemically amplified resist film; maintaining the temperature of the chemically amplified resist film at the first temperature for a predetermined time; increasing the temperature of the chemically amplified resist film to a second temperature which is not lower than the reaction start temperature after a lapse of the predetermined time; decreasing the temperature of the chemically amplified resist film increased to the second temperature to a temperature lower than the reaction start temperature; and developing the chemically amplified resist film to form a resist pattern after the decreasing the temperature.

According to another aspect of the present invention, there is provided a resist pattern forming method comprising: forming a chemically amplified resist film on a substrate; forming a latent image in the chemically amplified resist film by irradiating an energy ray onto a predetermined position on the chemically amplified resist film; contacting a liquid to a surface of the chemically amplified resist film; exposing the chemically amplified resist film in a reduced pressure atmosphere after the forming the latent image and after the contacting; increasing temperature of the chemically amplified resist film exposed in the reduced pressure atmosphere to a first temperature, the first temperature being not less than a reaction start temperature at which an acid catalysis reaction occurs in the chemically amplified resist film; decreasing the temperature of the chemically amplified resist film to a temperature lower than the reaction start temperature after the increasing the temperature; and developing the chemically amplified resist film to form a resist pattern after the decreasing the temperature.

According to an aspect of the present invention, there is provided a method of manufacturing a semiconductor device comprising: preparing a substrate including a semiconductor substrate; and forming a resist pattern on the substrate using a resist pattern forming method, the resist pattern forming method comprising: forming a chemically amplified resist film on a substrate; forming a latent image in the chemically amplified resist film by irradiating an energy ray onto a predetermined position on the chemically amplified resist film; contacting a liquid to a surface of the chemically amplified resist film; increasing temperature of the chemically amplified resist film to a first temperature after the forming the latent image and after the contacting, the first temperature being lower than a reaction start temperature at which an acid catalysis reaction occurs in the chemically amplified resist film; maintaining the temperature of the chemically amplified resist film at the first temperature for a predetermined time; increasing the temperature of the chemically amplified resist film to a second temperature which is not lower than the reaction start temperature after a lapse of the predetermined time; decreasing the temperature of the chemically amplified resist film increased to the second temperature to a temperature lower than the reaction start temperature; and developing the chemically amplified resist film to form a resist pattern after the decreasing the temperature.

According to another aspect of the present invention, there is provided a method of manufacturing a semiconductor device comprising: forming a chemically amplified resist film on a substrate; forming a latent image in the chemically amplified resist film by irradiating an energy ray onto a predetermined position on the chemically amplified resist film; contacting a liquid to a surface of the chemically amplified resist film; exposing the chemically amplified resist film in a reduced pressure atmosphere after the forming the latent image and after the contacting; increasing temperature of the chemically amplified resist film exposed in the reduced pressure atmosphere to a first temperature, the first temperature being not less than a reaction start temperature at which an acid catalysis reaction occurs in the chemically amplified resist film; decreasing the temperature of the chemically amplified resist film to a temperature lower than the reaction start temperature after the increasing the temperature; and developing the chemically amplified resist film to form a resist pattern after the decreasing the temperature.

### BRIEF DESCRIPTION OF THE SEVERAL VIEWS OF THE DRAWING

FIG. 1 is a flow chart showing steps of a method of manufacturing a semiconductor device according to a first embodiment;

FIG. 2 is a view showing a schematic configuration of an exposure apparatus according to the first embodiment;

FIG. 3 is a view showing a schematic configuration of a chamber according to the first embodiment;

FIG. 4 is a graph showing the time change of substrate temperatures in a PEB process according to the first embodiment;

FIGS. 5A and 5B are views each showing a chemical liquid removing process after immersion exposure according to the first embodiment;

FIG. 6 is a flow chart showing steps of a method of manufacturing a semiconductor device according to a second embodiment;

FIG. 7 is a schematic view showing a structure of a first chamber which performs dry process in reduced pressure atmosphere according to the second embodiment; and

FIG. 8 is a graph showing time change of substrate temperatures in PEB process and pressure in the chamber according to the second embodiment.

### DETAILED DESCRIPTION OF THE INVENTION

Embodiments of the present invention will be illustrated in more details with reference to the accompanying drawings hereinafter.

### First Embodiment

FIG. 1 is a flow chart showing the steps of a method of manufacturing a semiconductor device according to a first embodiment.

First, a reflection prevention film application material is dropped onto a semiconductor substrate. The reflection prevention film application material is spread on the semiconductor substrate by rotating the semiconductor substrate. Thereafter, the reflection prevention film application material is heated. As a result, a reflection prevention film is formed (step ST101). Here, the thickness of the reflection prevention film is approximately 50 nm.

Next, an ArF chemically amplified resist film including an acid generating material is formed on the reflection prevention film (step ST102). Here, the thickness of the ArF chemically amplified resist film is 200 nm. The chemically amplified resist film is formed in the following process. A chemically amplified resist application material is spread onto the reflection prevention film by a spin coat method. The chemically amplified resist application material is heated, and thereby, a solvent included in the chemically amplified resist application material is removed. As a result, the chemically amplified resist film is formed.

Next, the semiconductor substrate is set in a scan exposure apparatus (step ST103).

Next, by use of the scan exposure apparatus, a semiconductor element pattern formed on a reticle is transferred onto the chemically amplified resist film, and thereby, a latent image is formed in the chemically amplified resist film (step ST104).

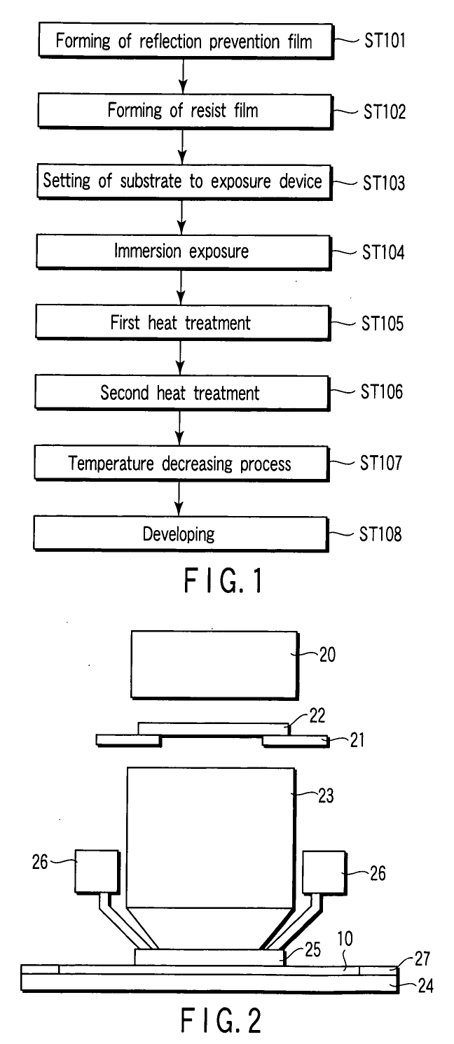

The scan exposure apparatus employed in the present embodiment is of an immersion exposure type. FIG. 2 shows a schematic configuration of the exposure apparatus according to the present embodiment. A reticle stage 21 is arranged below an illumination optical system 20. A reticle 22 is provided on the reticle stage 21. The reticle stage 21 can move parallel in the horizontal direction. A projection lens system 23 is arranged below the reticle stage 21. A wafer stage 24 is arranged below the projection lens system 23. The semiconductor substrate 10, which the above-mentioned treatment is performed, is provided on the wafer stage 24. The wafer stage 24 moves parallel together with the semiconductor substrate 10. A support plate 27 is arranged around the semiconductor substrate 10.

A fence 25 is attached to the underside of the projection lens system 23. At the sides of the projection lens system 23, a pair of water supply and discharge units 26 which supplies water (immersion solution) to the fence 25 and discharges water from the fence 25 is arranged. At the time of exposure, the space between the substrate 10 in the area surrounded by the fence 25 and the projection lens system 23 and the projection lens system 23 is filled with a liquid film of water. Exposure light irradiated from the projection lens system 23 goes through the water layer (the liquid film of the water) and reaches a radiation area. An image of a mask pattern (not shown) of the reticle 22 is projected on the chemically amplified resist film where corresponds to the radiation area, and a latent image is formed in the chemically amplified resist film.

Next, heat treatment at 70° C. for 60 seconds is performed to the semiconductor substrate in the first chamber (step ST105).

Next, the semiconductor substrate is carried into the second chamber. Heat treatment (post exposure bake (PEB) process) at 130° C. for 60 seconds is performed to the semiconductor substrate in the second chamber (step ST106). By the heat treatment (the PEB process), the diffusion and amplification reaction of an acid catalysis that occurs in the exposure stage is carried out.

Next, the semiconductor substrate is carried into a temperature decreasing chamber. The semiconductor substrate is cooled down in the temperature decreasing chamber until the temperature becomes 23° C. (step ST107).

Next, the semiconductor substrate is carried into a developing unit. A developing process is performed in the developing unit (step ST108). As a result, a resist pattern (ArF resist pattern) is formed.

The cross section of the resist pattern formed by the above steps (steps ST101 to ST108) is observed by use of a scanning electron microscope (SEM), and the unevenness of a line and space pattern of 1:1 of 60 nm on the wafer surface is 3σ: 3.0 nm. Meanwhile, the in-plane unevenness in the case where a PEB process to which the method of the present embodiment is not applied is performed is deteriorated as 3σ: 10.0 nm.

Next, the operation of the PEB process in the above-mentioned embodiment will be explained in detail hereinafter.

First, a first heating plate is maintained at a set temperature T₁ (for example, 70° C.) as a first predetermined temperature, a second heating plate is maintained at a set temperature (for example, 130° C.) as a second predetermined temperature, and a temperature decreasing plate is adjusted so as to become a set temperature T₃ (for example, 23° C.).

Next, the substrate 10 is carried into a first chamber 31. A substrate carrying port (not shown) of the first chamber 31 is opened. The substrate 10 is transported by a transportation arm, and the substrate 10 is set on the upper side of a first heating plate 33. At this moment, the substrate 10 is supported by elevation pins 32 which wait beforehand at a predetermined position on the upper side of a supporting base.

Next, the transportation arm is put out from the chamber 31. Thereafter, the elevation pins 32 go down, so that the substrate 10 is put on the first heating plate 33. At the same time when the substrate 10 is put on the first heating plate 33, the temperature increasing of the substrate 10 is started, and the substrate temperature is increased from 23° C. to 70° C. as shown in FIG. 4. In a state in which the substrate 10 reaches 70° C., the temperature is maintained for a predetermined time. At the stage after the lapse of the predetermined time period, the process in the first chamber 31 is finished. The substrate 10 is raised again by the elevation pins 32. Then, the substrate carrying port is opened, and the first chamber 31 is released from an airtight space.

After the lapse of the predetermined time, the substrate 10 is raised again by the elevation pins 32, and the temperature increasing of the substrate 10 by the first heating plate 33 is finished. Next, the substrate carrying port is opened, and the first chamber 31 is released.

Next, the substrate 10 is moved to the upper side of the heating plate of the second chamber by the transportation arm. The second chamber has the same structure as the first chamber, and therefore, the illustration thereof is omitted herein. Basically, the moved substrate 10 is received by the elevation pins, and in the same manner as in the first chamber, the substrate 10 is supported on the heating plate of the second chamber.

When the substrate 10 is put on the second heating plate, the substrate temperature is increased from 70° C. to 130° C. as shown in FIG. 4. At this moment, when 80° C. as the acid catalysis reaction start temperature T₀ of the chemically amplified resist film is exceeded, the reaction of the chemically amplified resist film starts. Meanwhile, the reaction start temperature is determined by the kind of the chemically amplified resist film.

The substrate 10 is then heated at 130° C. for a predetermined time. After the predetermined time, the substrate 10 is raised by the elevation pins, and the heat treatment, i.e., the PEB process of the substrate 10 is finished.

Next, when the substrate carrying port goes up, and the second chamber is released, the substrate 10 is transported to the temperature decreasing plate by the transportation arm. The substrate 10 transported to the temperature decrease plate is delivered to the elevation pins, thereafter, the substrate 10 is lowered to be put on the temperature decreasing plate. At this moment, the temperature decreasing of the substrate 10 is started, and the temperature of the substrate 10 is decreased from 130° C. to 23° C. as shown in FIG. 4. Along with this, the temperature of the chemically amplified resist film decreases, and thereby, the acid catalysis reaction of the chemical amplification resist film stops.

When the temperature of the substrate 10 reaches 23° C., and the temperature decreasing process is finished, the substrate 10 is raised by the elevation pins, the transportation arm receives the substrate 10 from the elevation pins, and the substrate 10 is taken out of the process chamber, so that the series of PEB process and the cleaning process is finished.

In the present embodiment, the temperature of the substrate 10 is once increased to the set temperature T₁ which is lower than the acid catalysis reaction start temperature of the chemically amplified resist film, and the state is maintained for a predetermined time, so that water included in the chemically amplified resist film is vaporized. Thereafter, by the second heating plate, the temperature of the substrate 10 is increased to the set temperature T₂ exceeding the reaction start temperature T₀. Before the acid catalysis reaction, water included in the chemically amplified resist film is vaporized at the temperature not higher than the acid catalysis reaction start temperature, whereby, at the next acid catalysis reaction in the second chamber, a part of the given heat is not lost as vaporization heat of water. Accordingly, the acid catalysis reaction fully progresses. Consequently, to the dimension unevenness arising from the liquid film that is formed unevenly on the surface of the resist film after the immersion exposure on the substrate surface, the line width of a pattern finally formed can be made even on the substrate surface. That is, according to the present embodiment, it is possible to prevent a pattern error from occurring in such a manner that, before the chemically amplified resist film is heated to the reaction start temperature at which the acid catalysis reaction occurs or higher, water included in the chemically amplified resist film is vaporized.

In the present embodiment, the heat treatment at the first set temperature and the heat treatment at the second set temperature are carried out in respectively different process chambers, however, the method of the heat treatment (PEB process) is not limited thereto. For example, a PEB process may be employed, where in a same process chamber, the substrate is processed first at the first set temperature, and thereafter, the substrate temperature is increased to the second set temperature.

Further, in the present embodiment, the heating plate temperature (T₁) of the first chamber is 70° C., but the temperature is not limited thereto. The heating plate temperature (T₁) of the first chamber may be appropriately optimal temperature according to the chemically amplified resist film to be used.

However, if the heating plate temperature (T₁) of the first chamber is too low, water on the substrate cannot be vaporized sufficiently, and thus, the effects described in the present embodiment cannot be attained sufficiently. Therefore, it is preferable that the heating plate temperature (T₁) of the first chamber is in the range from the reaction start temperature (T₀) of the chemically amplified resist film to T₀-20° C., and the temperature 10° C. lower than the reaction start temperature (T₀) is most suitable.

Further, in the present embodiment, deaerated pure water is used as the water to be interposed between the lens and the substrate to be processed at the time of the immersion exposure, but the water is not limited thereto. For example, in order to make the refractive index larger, a liquid with addition of an alkali ion of Group I, Group II or the like, or in order to make the absorption coefficient smaller, a liquid with addition of an acid ion may be used. In the case where an exposure apparatus whose absorption coefficient to exposure light is small and which is adjusted to a specific refractive index is used, any liquid having the specific refractive index and giving no damage to the lens system or the like may be used.

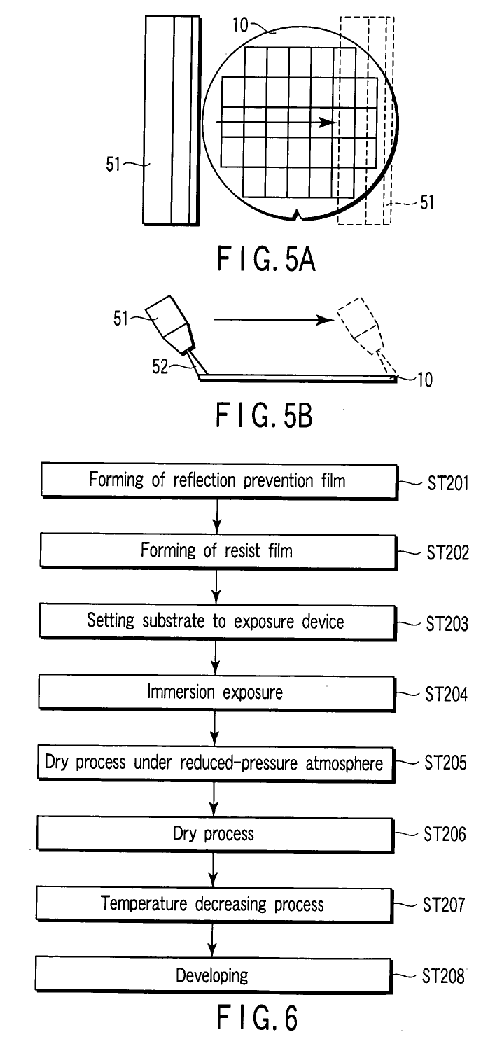

Further, after the immersion exposure and in prior to the PEB process, a rough dry process may be performed onto the resist film surface. The dry process comprises, for example, as shown in FIGS. 5A and 5B, a process for spraying gas 52 in which acid and alkali are filtered from an air knife 51 to a main surface of the substrate 10. The area where the air knife 51 sprays air onto the substrate 10 is a part of the surface of the substrate 10. In order to spray air onto the entire surface of the substrate 10, the air knife 51 is scanned on the surface of the substrate 10 from one end to the other end in the circumferential direction of the substrate 10. At this moment, the substrate 10 may be rotated or posed.

FIG. 5 is a view showing a pure water removal process according to the present embodiment. FIG. 5A is a plan view showing the state where the pure water removal process is carried out, and FIG. 5B is a side view showing the state where the pure water removal process is carried out. It is preferred that the direction of the gas 52 sprayed from the air knife 51 is in the advancing direction of the air knife 51. By making these directions same, it is possible to remove water efficiently and in a short time. Further, the dry process method is not limited to this, a rotation dry method may be employed.

The present embodiment relates to exposure using ArF (193 nm) light, however, it is possible to carry out patterning precisely by performing the same process with regard to exposure using KeF (248 nm) light. Further, with F₂ light (157 nm) exposure, it has bee confirmed that patterning can be performed precisely by performing the same process when fluorine system oil is used as a first solvent.

Here, the PEB process in the immersion exposure process is explained, however, the method of the present embodiment can be applied to other heat treatment as well. For example, the method of the present embodiment is also applicable to a case where a chemical liquid unevenly distributed on a surface layer of a chemically amplified resist film is removed when a chemical liquid process for the purpose of the surface treatment of the chemically amplified resist film or the like is carried out before or after an exposure process. In this case, it is also confirmed that patterning can be performed precisely by carrying out the same process. This chemical liquid process is, for example, the process disclosed in the third embodiment in Jpn. Pat. Appln. KOKAI Publication No. 2004-63490.

Further, explanation has been made for the case where the top surface layer of a substrate to be processed is a chemically amplified resist film, however, the method of the present embodiment can be applied to another film as well. For example, the method of the present embodiment can be applied to a case where a protective film for preventing water from getting into a chemically amplified resist film is formed on the chemically amplified resist film.

Here, when the formed protective film is not soluble in alkali such as a developing liquid, it is necessary to remove the formed protective film once from the resist film by supplying a protective film removing liquid by a special unit (removing unit) onto the substrate surface after the immersion exposure in the step ST104 in the flow chart shown in FIG. 1, and before the developing process in the step ST108.

On the other hand, in the case where the alkali soluble protective film is used, as the protective film can be removed by the supply of a developing liquid that is performed at the development in the step ST108, it is not necessary required to arrange the removing unit. In this case, depending on the chemically amplified resist film and the protective film to be used, the developing liquid temperature, the developing liquid concentration, the developing liquid supply time and the like may be set in appropriately most suitable conditions.

### Second Embodiment

FIG. 2 is a flow chart showing the steps of a method of manufacturing a semiconductor device according to a first embodiment.

First, a reflection prevention film application material is dropped onto a semiconductor substrate. The reflection prevention film application material is spread on the semiconductor substrate by rotating the semiconductor substrate. Thereafter, the reflection prevention film application material is heated. As a result, a reflection prevention film is formed (step ST201). Here, the thickness of the reflection prevention film is approximately 50 nm.

Next, an ArF chemically amplified resist film including an acid generating material is formed on the reflection prevention film (step ST202). Here, the thickness of the ArF chemically amplified resist film is 200 nm. The chemically amplified resist film is formed in the following process. A chemically amplified resist application material is spread onto the reflection prevention film by a spin coat method. The chemically amplified resist application material is heated, and thereby, a solvent included in the chemically amplified resist application material is removed. As a result, the chemically amplified resist film is formed.

Next, the semiconductor substrate is set in a scan exposure apparatus (step ST203).

Next, by use of the scan exposure apparatus, a semiconductor element pattern formed on a reticle is transferred onto the chemically amplified resist film, and thereby, a latent image is formed in the chemically amplified resist film (step ST204).

The exposure apparatus employed in the present embodiment is the immersion exposure type exposure apparatus shown in FIG. 2 same as the first embodiment.

Next, the semiconductor substrate is carried into a heat treatment apparatus, and a PEB process is performed to the semiconductor substrate. By the PEB process, the diffusion and amplification reaction of an acid catalysis that occurs in the exposure stage is carried out.

The PEB process is carried out as follows (FIG. 6).

First, the semiconductor substrate is carried into a first chamber of the heat treatment apparatus, further loaded. Next, the pressure of the first chamber is decreased from a normal pressure to a preset pressure. At the stage after a lapse of a predetermined time from the start of vacuuming, the process in the first chamber is finished (step ST205). After vacuuming is stopped, gas is supplied into the first chamber.

Next, the semiconductor substrate is transported from the first chamber to a second chamber. Thereafter, in the second chamber, heat treatment (dry process) at 130° C. for 60 seconds is performed to the semiconductor substrate (step ST206).

Thereafter, the semiconductor substrate is transported to a temperature decreasing chamber, and the semiconductor substrate is cooled down in the temperature decreasing chamber until the temperature becomes 23° C. (step ST207).

Thereafter, the semiconductor substrate is carried into a developing unit. A developing process is performed in the developing unit, and thereby, a resist pattern (ArF resist pattern) is formed (step ST208).

The cross section of the resist pattern formed by the above steps (steps ST201 to ST208) is observed by use of a SEM, and the unevenness of a line and space pattern of 1:1 of 60 nm in the wafer surface is 3σ: 3.0 nm. Meanwhile, the in-plane unevenness in the case where a PEB process to which the method of the present embodiment is not applied is performed is deteriorated as 3σ: 10.0 nm.

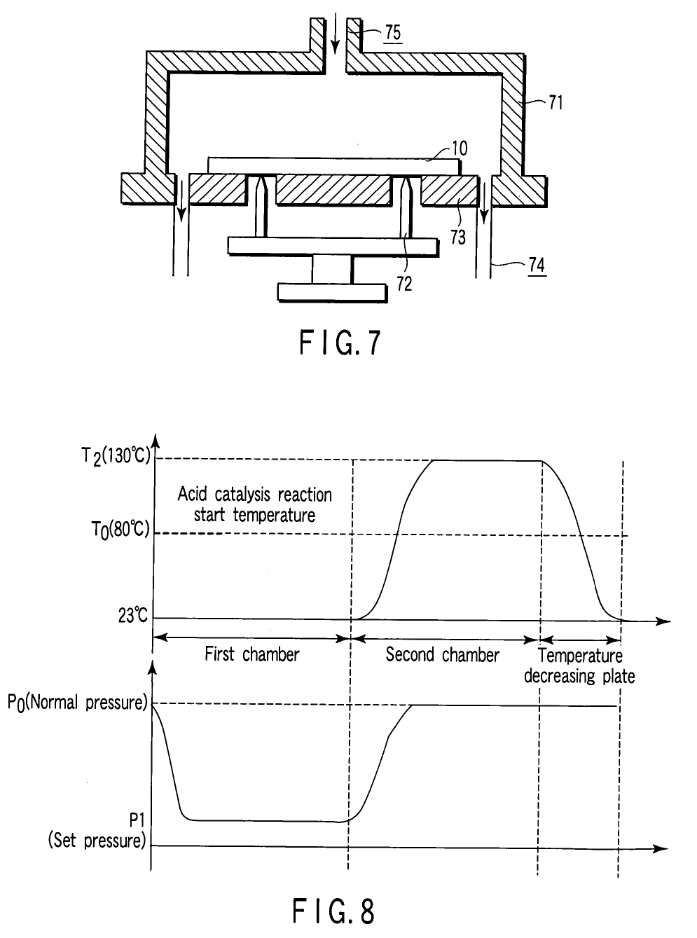

Next, the operation of the PEB process in the above-mentioned embodiment will be explained in detail hereinafter (FIG. 7).

First, the substrate 10 is carried into a first chamber 71. When the substrate 10 is carried, the inside of the first chamber 71 is initially maintained at a normal pressure by inert gas. The substrate carrying port of the first chamber 71 is opened, the substrate 10 is transported by a transportation arm, and the substrate 10 is set on the upper side of a supporting base of the first chamber 71. At this moment, the substrate 10 is supported by elevation pins 72 that wait beforehand at a predetermined position on the upper side of the supporting base 73.

Next, the transportation arm is put out from the chamber 71. Thereafter, the elevation pins 72 go down, and the substrate 10 is put on the supporting base 73.

When the substrate 10 is put on the supporting base 73, air discharge (vacuuming) from an air discharge port 74 in the first chamber 71 is started. In this vacuuming, as shown in FIG. 8, the pressure of the first chamber 71 may be simply decreased from the normal pressure P₀ to a set pressure P₁, or may be decreased gradually. At the stage after lapse of a predetermined time from the start of vacuuming, the dry process under the reduced pressure in the first chamber 71 is finished. The substrate 10 is raised again by the elevation pins 72. Next, the inert gas is absorbed from an intake port 75 to perform purging, thereafter, the substrate carrying port is opened, and the first chamber 71 is released from an airtight space.

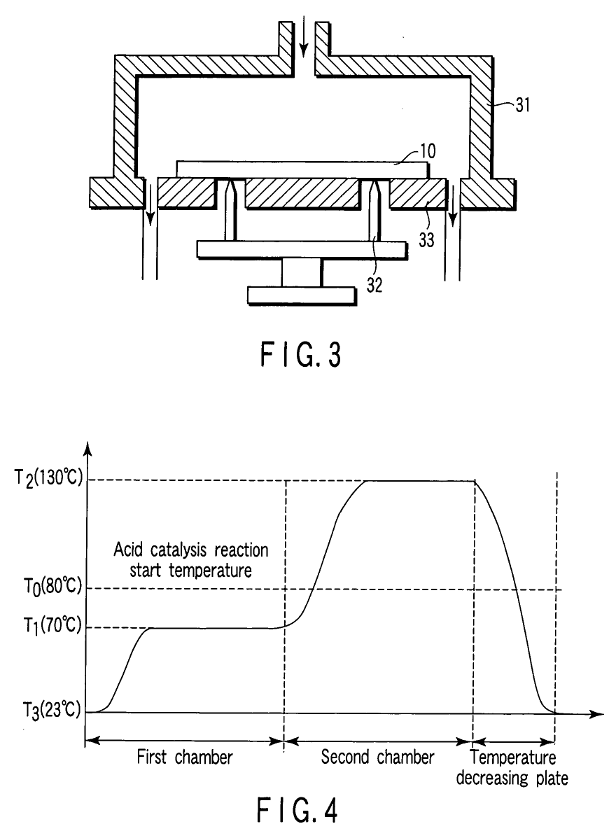

Next, the substrate 10 is moved to the upper surface of the second chamber by the transportation arm. The moved substrate 10 is received by the elevation pins, and in the same manner as in the first chamber, the substrate 10 is supported on the heating plate of the second chamber. The structure of the second chamber may be same as that of the chamber explained with reference to FIG. 3 in the first embodiment, and therefore, the figure and explanation thereof are omitted herein.

When the substrate 10 is put on the heating plate 10 of the second chamber, the substrate temperature is increased to 130° C. After a lapse of a predetermined time, the heat treatment, i.e., the PEB process in the second chamber is finished.

Next, the substrate 10 is raised again by the elevation pins, the substrate carrying port is opened, and the second chamber is released, whereby the substrate 10 is transported from the second chamber to the temperature decreasing plate. The substrate 10 transported to the temperature decreasing plate is delivered to the elevation pins, thereafter, the substrate 10 is lowered to be put on the temperature decreasing plate. At this moment, the temperature decreasing of the substrate 10 is started, and the temperature of the substrate 10 is decreased from 130° C. to 23° C. At this moment, the temperature of the chemically amplified resist film decreases, so that the acid catalysis reaction of the chemical amplification resist film is stopped.

When the temperature of the substrate reaches 23° C., and the temperature decreasing process is finished, the substrate 10 is raised by the elevation pins, the transportation arm receives the substrate 10 from the elevation pins, and the substrate 10 is taken out of the process chamber, so that the series of PEB process and the cleaning process is finished.

In the present embodiment, the substrate 10 is maintained for the predetermined time in the first chamber for gradually decompressing from the normal pressure state under normal temperatures to the set pressure P₁ with the low vacuum degree, whereby water included in the chemically amplified resist film on the substrate 10 is vaporized.

Thereafter, in the second chamber, the temperature of the substrate 10 is increased to the temperature over the reaction start temperature, thereby the acid catalysis reaction occurs. Thus, before the acid catalysis reaction, the drying is performed in the reduced pressure atmosphere at the temperature that the acid catalysis reaction occurs (reaction temperature) or lower than the reaction temperature, whereby water included in the chemically amplified resist film is vaporized. Consequently, at the next acid catalysis reaction in the second chamber, a part of the given heat is not lost as vaporization heat of water. Accordingly, the acid catalysis reaction progresses fully.

The liquid film that occurs unevenly on the surface of the chemically amplified resist film after the immersion exposure causes dimension unevenness. However, since the acid catalysis reaction progresses fully in the present embodiment, the line width of the pattern finally formed can be made even on the substrate surface. That is, according to the present embodiment, it is possible to prevent a pattern error from occurring in such a manner that, before the chemically amplified resist film is heated to the reaction start temperature at which the acid catalysis reaction occurs or higher, water included in the chemically amplified resist film is vaporized.

Meanwhile, in the present embodiment, the decompression dry process is carried out at the normal temperature (23° C.) in the first chamber. However, the temperature in the first chamber, namely, the atmospheric temperature (process temperature) at which the dry process under the reduced pressure is carried out is not limited thereto. That is, the process temperature may be appropriately selected in the temperature range lower than the acid catalysis reaction start temperature.

The pressure in the first chamber may be also appropriately selected according to the process time and various resist films. For example, in the case where the first chamber is a chamber having a temperature variable heating plate, having a variable inside pressure, and having a substrate set in the inside thereof, the following may be selected. When the pressure in the chamber decreases, the dry under the reduced pressure is carried out at a first set temperature for a predetermined time. Thereafter, the pressure in the chamber is recovered to the normal pressure, and further, the substrate temperature is increased to a second set temperature. In this manner, the PEB process may be performed.

However, in a case that a chamber whose inside temperature can be controlled is used as the first chamber and the temperature in the chamber exceeds the reaction start temperature (T₀) at the set pressure (P₁), water on the substrate is vaporized and an acid catalysis reaction occurs at the same time, and accordingly, it becomes difficult to control the acid catalysis reaction. Therefore, it is preferable that the heating plate temperature of the chamber is controlled so as to be lower than the reaction start temperature (T₀) at the set pressure (P₁).

Further, in the present embodiment, deaerated pure water is used as the water to be interposed between the lens and the substrate to be processed at the immersion exposure, but the present invention is not limited thereto. For example, in order to make the refractive index large, a liquid with addition of an alkali ion of Group I, Group II or the like, or in order to make the absorption coefficient small, a liquid with addition of an acid ion may be employed. In the case where an exposure apparatus whose absorption coefficient to exposure light is small and which is adjusted to a specific refractive index is employed, any liquid having the specific refractive index and giving no damage to the lens system or the like may be employed as the liquid.

In addition, after the immersion exposure and in prior to the PEB process, a rough dry process may be made to the resist film surface. The dry process is, for example, same as the dry process explained in the first embodiment (FIGS. 5A and 5B).

The present embodiment relates to exposure using ArF (193 nm) light, however, it is possible to carry out patterning precisely by performing the same process with regard to exposure using KeF (248 nm) light. Further, with F₂ light (157 nm) exposure, it has bee confirmed that patterning can be performed precisely by performing the same process when fluorine system oil is used as a first solvent.

Here, the PEB process in the immersion exposure process is explained, however, the method of the present embodiment can be applied to other heat treatment as well. For example, the method of the present embodiment is also applicable to a case where a chemical liquid unevenly distributed on a surface layer of a chemically amplified resist film is removed when a chemical liquid process for the purpose of the surface treatment of the chemically amplified resist film or the like is carried out before or after an exposure process. In this case, it is also confirmed that patterning can be performed precisely by carrying out the same process. This chemical liquid process is, for example, the process disclosed in the third embodiment in Jpn. Pat. Appln. KOKAI Publication No. 2004-63490.

Further, explanation has been made for the case where the top surface layer of a substrate to be processed is a chemically amplified resist film, however, the method of the present embodiment can be applied to another film as well. For example, the method of the present embodiment can be applied to a case where a protective film for preventing water from getting into a chemically amplified resist film is formed on the chemically amplified resist film.

Here, when the formed protective film is not soluble in alkali such as a developing liquid, it is necessary to remove the formed protective film once from the resist film by supplying a protective film removing liquid by a special unit (removing unit) onto the substrate surface after the immersion exposure in the step ST104 in the flow chart shown in FIG. 1, and before the developing process in the step ST108.

On the other hand, in the case where the alkali soluble protective film is used, as the protective film can be removed by the supply of a developing liquid that is performed at the development in the step ST108, it is not necessary required to arrange the removing unit. In this case, depending on the chemically amplified resist film and the protective film to be used, the developing liquid temperature, the developing liquid concentration, the developing liquid supply time and the like may be set in appropriately most suitable conditions.

In the respective embodiments, the resist pattern forming process as a part of a method of manufacturing a semiconductor device has been explained. The explained resist pattern forming process may be applied further to a method of manufacturing an image pickup device (CCD and the like), a liquid crystal display device, or a thin film magnetic head, etc.

The method of manufacturing a semiconductor device of the present embodiments includes forming a resist pattern on a substrate including a semiconductor substrate by use of the resist pattern forming method of any of the above-mentioned embodiments. The method of manufacturing a semiconductor device of the present embodiments further may include etching the substrate using the resist pattern as a mask, and removing the resist pattern.

The substrate including the semiconductor substrate is a semiconductor substrate itself such as a silicon substrate, and a substrate including a semiconductor substrate and an insulation film or a conductive film formed on the semiconductor substrate. When the semiconductor substrate itself is etched, the process of etching the substrate is, for example, the etching process at the time of forming an isolation trench. When a substrate including an insulation film and the like is etched, the process of etching the substrate is, for example, the etching process at the time of forming a contact hole or a wiring trench. The semiconductor device is a device using a semiconductor element, and is, for example, a semiconductor memory or a liquid crystal display device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A resist pattern forming method comprising:
forming a chemically amplified resist film on a substrate;
forming a latent image in the chemically amplified resist film by irradiating an energy ray onto a predetermined position on the chemically amplified resist film;
contacting a liquid to a surface of the chemically amplified resist film;
increasing temperature of the chemically amplified resist film to a first temperature after the forming the latent image and after the contacting, the first temperature being lower than a reaction start temperature at which an acid catalysis reaction occurs in the chemically amplified resist film;
maintaining the temperature of the chemically amplified resist film at the first temperature for a predetermined time;
increasing the temperature of the chemically amplified resist film to a second temperature that is not lower than the reaction start temperature after a lapse of the predetermined time;
decreasing the temperature of the chemically amplified resist film increased to the second temperature to a temperature lower than the reaction start temperature; and
developing the chemically amplified resist film to form a resist pattern after the decreasing the temperature.

2. A resist pattern forming method comprising:
forming a chemically amplified resist film on a substrate;
forming a latent image in the chemically amplified resist film by irradiating an energy ray onto a predetermined position on the chemically amplified resist film;
contacting a liquid to a surface of the chemically amplified resist film;
exposing the chemically amplified resist film in a reduced pressure atmosphere after the forming the latent image and after the contacting;
increasing temperature of the chemically amplified resist film exposed in the reduced pressure atmosphere to a first temperature, the first temperature being not less than a reaction start temperature at which an acid catalysis reaction occurs in the chemically amplified resist film;
decreasing the temperature of the chemically amplified resist film to a temperature lower than the reaction start temperature after the increasing the temperature; and
developing the chemically amplified resist film to form a resist pattern after the decreasing the temperature.

3. The resist pattern forming method according to claim 2, wherein the temperature of the chemically amplified resist film is increased to a temperature lower than the reaction start temperature when the chemically amplified resist film is exposed in the reduced pressure atmosphere.

4. The resist pattern forming method according to claim 1, wherein the forming the latent image in the chemically amplified resist film includes performing immersion exposure process to the chemically amplified resist film, and further comprising forming a protective film on the chemically amplified resist film before the performing the immersion exposure process; and removing the protective film after the performing the immersion exposure process and before the developing the chemically amplified resist film.

5. The resist pattern forming method according to claim 2, wherein the forming the latent image in the chemically amplified resist film includes performing immersion exposure process to the chemically amplified resist film, and further comprising forming a protective film on the chemically amplified resist film before the performing the immersion exposure process; and removing the protective film after the performing the immersion exposure process and before the developing the chemically amplified resist film.

6. The resist pattern forming method according to claim 1, wherein the energy ray is a laser.

7. The resist pattern forming method according to claim 6, wherein the laser is an ArF laser or F₂ laser.

8. The resist pattern forming method according to claim 1, wherein the liquid is pure water, a liquid in which an alkali ion is added or a liquid in which an acid ion is added.

9. The resist pattern forming method according to claim 2, wherein the energy ray is a laser.

10. The resist pattern forming method according to claim 9, wherein the laser is an ArF laser, F₂ laser, or KrF laser.

11. The resist pattern forming method according to claim 2, wherein the liquid is pure water, a liquid in which an alkali ion is added or a liquid in which an acid ion is added.

12. A method of manufacturing a semiconductor device comprising:
preparing a substrate including a semiconductor substrate; and
forming a resist pattern on the substrate using a resist pattern forming method,
the resist pattern forming method comprising: forming a chemically amplified resist film on a substrate;
forming a latent image in the chemically amplified resist film by irradiating an energy ray onto a predetermined position on the chemically amplified resist film;
contacting a liquid to a surface of the chemically amplified resist film;
increasing temperature of the chemically amplified resist film to a first temperature after the forming the latent image and after the contacting, the first temperature being lower than a reaction start temperature at which an acid catalysis reaction occurs in the chemically amplified resist film;
maintaining the temperature of the chemically amplified resist film at the first temperature for a predetermined time;
increasing the temperature of the chemically amplified resist film to a second temperature that is not lower than the reaction start temperature after a lapse of the predetermined time;
decreasing the temperature of the chemically amplified resist film increased to the second temperature to a temperature lower than the reaction start temperature; and
developing the chemically amplified resist film to form a resist pattern after the decreasing the temperature.

13. A method of manufacturing a semiconductor device comprising:
forming a chemically amplified resist film on a substrate;
forming a latent image in the chemically amplified resist film by irradiating an energy ray onto a predetermined position on the chemically amplified resist film;
contacting a liquid to a surface of the chemically amplified resist film;
exposing the chemically amplified resist film in a reduced pressure atmosphere after the forming the latent image and after the contacting;
increasing temperature of the chemically amplified resist film exposed in the reduced pressure atmosphere to a first temperature, the first temperature being not less than a reaction start temperature at which an acid catalysis reaction occurs in the chemically amplified resist film;
decreasing the temperature of the chemically amplified resist film to a temperature lower than the reaction start temperature after the increasing the temperature; and
developing the chemically amplified resist film to form a resist pattern after the decreasing the temperature.

14. The method of manufacturing a semiconductor device according to claim 13, wherein the temperature of the chemically amplified resist film is increased to a temperature lower than the reaction start temperature when the chemically amplified resist film is exposed in the reduced pressure atmosphere.

15. The method of manufacturing a semiconductor device according to claim 12, wherein the forming the latent image in the chemically amplified resist film includes performing immersion exposure process to the chemically amplified resist film, and further comprising forming a protective film on the chemically amplified resist film before the performing the immersion exposure process; and removing the protective film after the performing the immersion exposure process and before the developing the chemically amplified resist film.

16. The method of manufacturing a semiconductor device according to claim 13, wherein the forming the latent image in the chemically amplified resist film includes performing immersion exposure process to the chemically amplified resist film, and further comprising forming a protective film on the chemically amplified resist film before the performing the immersion exposure process; and removing the protective film after the performing the immersion exposure process and before the developing the chemically amplified resist film.
